(19) United States
(12) Patent Application Publication
(10) Pub. No.: US 2020/0220000 A1
(43) Pub. Date: Jul. 9, 2020

(54) GaN-Based HEMT Device

(71) Applicant: Waython Intelligent Technologies Suzhou Co., Ltd., Suzhou, JI (CN)

(72) Inventors: Honggang Liu, Suzhou (CN); Hudong Chang, Suzhou (CN); Bing Sun, Suzhou (CN)

(73) Assignee: Waython Intelligent Technologies Suzhou Co., Ltd., Suzhou, JI (CN)

(21) Appl. No.: 16/627,534

(22) PCT Filed: Mar. 8, 2019
(86) PCT No.: PCT/CN2019/077476

§ 371 Date: Dec. 30, 2019

(30) Foreign Application Priority Data
Apr. 20, 2018 (CN) 201810360107.5

(51) Int. Cl. H01L 29/778; H01L 29/20; H01L 29/423

(52) U.S. Cl. CPC H01L 29/7783; H01L 29/4232; H01L 29/2003

(57) ABSTRACT

The present disclosure discloses a GaN-based HEMT device, comprising a gate electrode, a source electrode, and a drain electrode, and further comprising a substrate, a buffer layer, a GaN channel layer, a first barrier layer, a second barrier layer and a dielectric passivation layer, the buffer layer being sequentially stacked from bottom to top, wherein an N-type ion injection region is formed in the GaN channel layer and the first barrier layer, the source electrode and the drain electrode are formed on an upper surface of the N-type ion-implanted region; the gate electrode is formed on an upper surface of the first barrier layer and is located between the source electrode and the drain electrode; and the dielectric passivation layer encircles the gate electrode so as to isolate the gate electrode from the N-type ion-implanted region.

### CROSS-REFERENCE TO RELATED APPLICATIONS

This application claims the priority of Chinese patent application CN201810360107.5, filed Apr. 20, 2018, which is incorporated herein by reference in its entirety.

### TECHNICAL FIELD OF THE INVENTION

The present disclosure relates to the semiconductor device field, in particular to a GaN-based HEMT device.

### BACKGROUND OF THE INVENTION

The wide bandgap semiconductor gallium nitride (GaN) material is an ideal material for a new generation of semiconductor power devices due to its large band-gap width, high critical breakdown electric field, and high electron saturation speed. In recent years, the GaN-based HEMT device structure represented by Al(In, Ga, Sc)N/GaN has become a mainstream GaN-based HEMT device material structure by means of a high two-dimensional electron gas generated by spontaneous polarization and piezoelectric polarization.

At present, the main application fields of GaN devices are high frequency, high voltage and high power integrated circuits, the performance of the device is mainly improved by the high band gap width and high two-dimensional electron gas concentration of GaN materials, and how to apply GaN devices to mobile phone chips has become an important research.

In order to enable the GaN device to successfully operate in the cell phone voltage range, the source-drain spacing of the GaN HEMT device needs to be further reduced, and the on-resistance of the device also needs to be further reduced. In order to achieve a reduction in the on-resistance of the device, the usual technical means is to reduce the source-drain spacing. However, for GaN devices, simply reducing the source-drain spacing and the high-temperature alloy process of the device will conflict, and if the alloy temperature is too high, the metal diffusion pattern in the alloy junction will be irregular and unsmooth, the source-drain spacing will be too small, which will easily result in a source-drain punch-through, and cause failure of GaN devices.

### SUMMARY OF THE INVENTION

The present disclosure is intended to solve the deficiencies and problems in the prior art above, and provides a GaN-based HEMT device, which on the premise of no influence on reliability of the device, reduces the source-drain parasitic resistance, decreases the on-resistance of the GaN-based HEMT device, and enable the GaN-based HEMT device to operate at a low voltage.

To achieve the above mentioned purpose, the technical solution employed by the present disclosure is as follows:

a GaN-based HEMT device, comprises a gate electrode, a source electrode, a drain electrode, a substrate, a buffer layer, a GaN channel layer, a first barrier layer, a second barrier layer and a dielectric passivation layer, the substrate, the buffer layer, the GaN channel layer, the first barrier layer, the second barrier layer and the dielectric passivation layer being sequentially stacked from bottom to top;
an N-type ion-implanted region is formed in the GaN channel layer and the first barrier layer, and the source electrode and the drain electrode are formed on an upper surface of the N-type ion-implanted region;
the gate electrode is formed on an upper surface of the first barrier layer and is located between the source electrode and the drain electrode;
the dielectric passivation layer encircles the gate electrode so as to isolate the gate electrode from the N-type ion-implanted region.

In an embodiment, a material of the first barrier layer is AlN or a combination of Al, N and one or two selected from In, Ga and Sc; the second barrier layer is an AlN barrier layer.

In an embodiment, the first barrier layer is an AlGaN, AlInN, AlScN, AlN, AlInGaN, AlInScN or AlGaScN barrier layer.

In an embodiment, the N-type ion-implanted region extends vertically downward from the upper surface of the first barrier layer into the GaN channel layer, and the N-type ion-implanted region extends into the GaN channel layer to a depth less than a thickness of the GaN channel layer.

In an embodiment, the N-type ion-implanted region extends into the GaN channel layer to a depth of 10-300 nm.

In an embodiment, an edge of the N-type ion-implanted region close to the gate electrode is aligned with an outside edge of the dielectric passivation layer.

In an embodiment, the N-type ion-implanted region is formed by one or multiple ion implantations.

In an embodiment, the dielectric passivation layer is a single layer structure, and the N-type ion-implanted region is formed by implanting N-type ions into the GaN channel layer and the first barrier layer after the dielectric passivation layer is formed.

In an embodiment, the dielectric passivation layer comprises a first dielectric layer and a second dielectric layer, and the N-type ion-implanted region is formed by implanting N-type ions into the GaN channel layer and the first barrier layer respectively after the first dielectric layer is formed and after the second dielectric layer is formed, and a portion of the edge of the N-type ion-implanted region close to the gate electrode is aligned with an outer edge of the first dielectric layer and another portion of the edge thereof is aligned with an outer edge of the second dielectric layer.

In an embodiment, the substrate is a single crystal substrate selected from single crystal silicon, gallium nitride, sapphire, and silicon carbide;

and/or, the buffer layer is a multilayer structure composed of at least two selected from AlN, GaN, and ALGaN.

In an embodiment, a thickness of the first barrier layer is 1-50 nm; a thickness of the second barrier layer is 1-10 nm; a thickness of the dielectric passivation layer is 10-300 nm, and a width thereof is 10-1000 nm.

By employing the above solution, the present disclosure has the following advantages over the prior art:

By forming an N-type ion-implanted region in the source and drain regions to form a heavily doped N-type GaN channel layer and barrier layer, and forming the source and drain electrodes on the heavily doped N-type GaN channel layer and barrier layer, firstly, the gate-source resistance and the gate-drain resistance are reduced by the ion-implanted region, and then the influence of metal diffusion on the gate electrode and the channel layer is reduced through ohmic contact of the heavily doped GaN channel layer and barrier layer with the source and drain electrodes. On the premise of no influence on reliability of the device, the source-drain parasitic resistance is reduced, the on-resistance of the GaN-based HEMT device is decreased, and the GaN-based HEMT device to operate at a low voltage is realized.

### BRIEF DESCRIPTION OF THE DRAWINGS

For more clearly explaining the technical solutions in the embodiments of the present disclosure, the accompanying drawings used to describe the embodiments are simply introduced in the following. Apparently, the below described drawings merely show a part of the embodiments of the present disclosure, and those skilled in the art can obtain other drawings according to the accompanying drawings without creative work.

FIG. 1 is a schematic cross-section diagram of a GaN-based HEMT device according to Embodiment 1 of the present disclosure;

FIG. 2 is a schematic cross-section diagram of a GaN-based HEMT device according to Embodiment 2 of the present disclosure;

FIG. 3 is a schematic cross-section diagram of a GaN-based HEMT device according to Embodiment 3 of the present disclosure;

wherein: 101—substrate; 102—buffer layer; 103—GaN channel layer; 104—first barrier layer; 105—second barrier layer; 106—SiN dielectric layer; 106a—outside edge; 107—SiO₂ dielectric layer; 107a—outside edge; 108—gate electrode; 109—drain electrode; 110—source electrode; 111—N-type ion-implanted region; 111a—edge; 111b—edge.

### DETAILED DESCRIPTION OF EXEMPLARY EMBODIMENTS

In the following, the preferable embodiments of the present disclosure are explained in detail combining with the accompanying drawings so that the advantages and features of the present disclosure can be easily understood by the skilled persons in the art. The definition of the orientation of the present disclosure is defined according to the conventional viewing angle of those skilled in the art and for convenience of description, and does not limit the specific direction. The above-mentioned orientation words, such as upper and lower, are defined according to the conventional viewing angle of those skilled in the art on the HEMT device and for convenience of description, and do not limit the specific directions, and taking FIG. 1 as an example, upper and lower respectively correspond to the upper side and the lower side of the paper surface in FIG. 1.

### Embodiment 1

FIG. 1 shows a schematic cross-section diagram of a GaN-based HEMT device provided by the present embodiment. Referring to FIG. 1, the GaN-based HEMT device comprises a substrate 101, a buffer layer 102, a GaN channel layer 103, a first barrier layer 104, a second barrier layer 105 and a dielectric passivation layer being sequentially stacked from bottom to top, and the GaN-based HEMT device further comprises a gate electrode 108, a drain electrode 109, a source electrode 110.

Wherein, the dielectric passivation layer is composed of one layer of a SiN dielectric layer 106 formed on the second barrier layer 105 and is equal to a width thereof, a window extending to an upper surface of the first barrier layer 104 is formed in the second barrier layer 105 and the SiN dielectric layer 106, a gate metal is deposited in the window to form the gate electrode 108, the gate electrode 108 is formed on the upper surface of the first barrier layer 104 and an upper portion thereof covers the upper surface of the SiN dielectric layer 106, and the second barrier layer 105 and the SiN dielectric layer 106 encircle the gate electrode 108. The cross section of the gate electrode 108 in this embodiment is substantially Y-shaped, and may also be T-shaped or mushroom-shaped.

An N-type ion-implanted region 111 is formed in the GaN channel layer 103 and the first barrier layer 104, and the implanted ions are Si. The source electrode 110 and the drain electrode 109 are respectively formed on an upper surface of the N-type ion-implanted region 111, and the SiN dielectric layer 106 as a sidewall structure isolates the gate electrode 108 between the source electrode 110 and the drain electrode 109 from the N-type ion-implanted region 111 and the source electrode 110 and the drain electrode 109 thereon, respectively. There is certain gap between the source electrode 110 and the SiN dielectric layer 106, and there is certain gap between the drain electrode 109 and the SiN dielectric layer 106.

The substrate 101 is a single crystal substrate 101, in particular, is a single crystal substrate selected from single crystal silicon, gallium nitride, sapphire, and silicon carbide.

The buffer layer 102 is an AlN/GaN buffer layer, which is a multilayer structure composed of at least two selected from AlN, GaN, and ALGaN.

The first barrier layer 104 is an Al(In, Ga, Sc)N barrier layer, a material thereof is AlN or a combination of Al, N and one or two selected from In, Ga and Sc, for example, an AlGaN, AlInN, AlScN, AlN, AlInGaN, AlInScN or AlGaScN barrier layer. A thickness thereof is 1-50 nm.

The second barrier layer 105 is an AlN barrier layer, a thickness thereof is 1-10 nm. The second barrier layer 105 has the same width as the SiN dielectric layer 106 formed thereon.

In this embodiment, the SiN dielectric layer 106 has a thickness of 10-300 nm and a width of 10-1000 nm. The dielectric passivation layer may also be a multilayer structure such as SiNx/SiO₂, SiNx/SiO₂/SiONₓ; or may also be a composite multilayer structure, such as a composite structure of SiO₂ material or SiON material close to the drain electrode 109, and SiNx/SiO₂ or SiN/SiON bilayer material close to the gate electrode 108.

The N-type ion-implanted region 111 extends vertically downward from the upper surface of the first barrier layer 104 into the GaN channel layer 103, and the N-type ion-implanted region 111 extends into the GaN channel layer 103 to a depth less than a thickness of the GaN channel layer 103. In this embodiment, an upper surface of the N-type ion-implanted region 111 is aligned with the upper surface of the first barrier layer 104, and the N-type ion-implanted region 111 extends into the GaN channel layer 103 to a depth of 10-300 nm. The N-type ion-implanted region 111 is formed by one ion implantation, that is to say, the N-type ion-implanted region 111 is formed by implanting N-type ions into the GaN channel layer 103 and the first barrier layer 104 for one time after the dielectric passivation layer is completely formed.

An edge 111a of the N-type ion-implanted region 111 close to the gate electrode 108 is aligned with an outside edge 106a of the dielectric passivation layer (specifically, the SiN dielectric layer 106), both of which extend along the same vertical direction, and the edge 111a of the N-type ion-implanted region 111 is positioned directly below the outside edge of the SiN dielectric layer 106, at least not deep into the sidewall structure, and the sidewall structure isolates the N-type ion region from the gate electrode 108.

### Embodiment 2

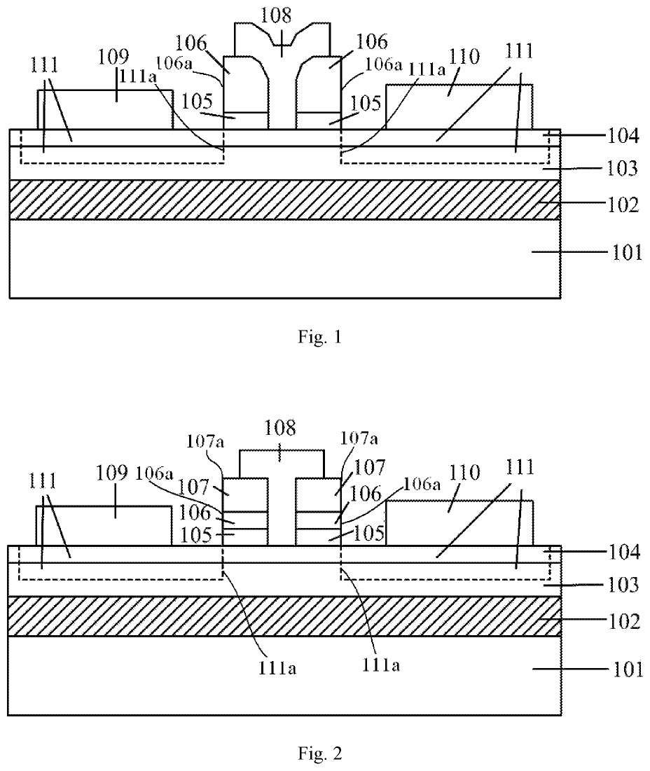

FIG. 2 shows a schematic cross-section diagram of another GaN-based HEMT device provided by the present embodiment. Referring to FIG. 2, this embodiment differs from Embodiment 1 by that: the dielectric passivation layer is a two-layer structure composed of a first dielectric layer formed on the second barrier layer 105 and a second dielectric layer formed on the first dielectric layer. The first dielectric layer is a SiN dielectric layer 106 and the second dielectric layer is a SiO₂ dielectric layer 107. The second barrier layer 105, the SiN dielectric layer 106 and the SiO₂ dielectric layer 107 have the same width, and the gate electrode 108 is formed in the second barrier layer 105, the SiN dielectric layer 106 and the SiO₂ dielectric layer 107, and the upper portion thereof covers an upper surface of the SiO₂ dielectric layer 107. The edge 111a of the N-type ion-implanted region 111 close to the gate electrode 108 is aligned with the outside edges 106a, 107a of the SiN dielectric layer 106 and the SiO₂ dielectric layer 107.

Moreover, in this embodiment, the cross section of the gate electrode 108 is substantially T-shaped.

### Embodiment 3

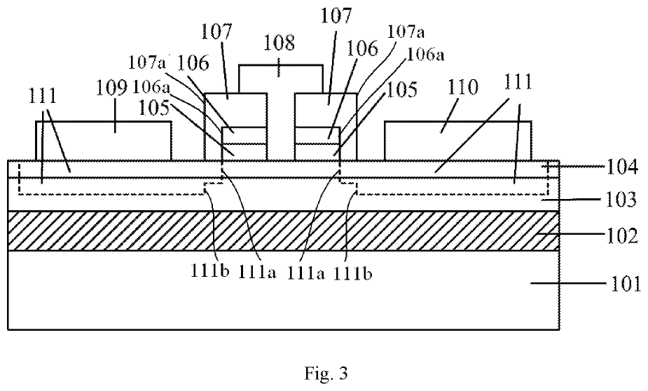

FIG. 3 shows a schematic cross-section diagram of yet another GaN-based HEMT device provided by the present embodiment. Referring to FIG. 3, this embodiment differs from Embodiment 1 by that: the dielectric passivation layer is a two-layer structure composed of a first dielectric layer and a second dielectric layer. The first dielectric layer is a SiN dielectric layer 106 and the second dielectric layer is a SiO₂ dielectric layer 107. The SiN dielectric layer 106 is formed on the upper surface of the second barrier layer 105, and the second barrier layer 105 and the SiN dielectric layer 106 have the same width; the SiO₂ dielectric layer 107 is formed by covering on the upper surface of the SiN dielectric layer 106 and side surfaces of the SiN dielectric layer 106 and the second barrier layer 105, and the width of the SiO₂ dielectric layer 107 is greater than the width of the SiN dielectric layer 106 and the second barrier layer 105. The gate electrode 108 is formed in the second barrier layer 105, the SiN dielectric layer 106 and the SiO₂ dielectric layer 107, and the upper portion thereof covers an upper surface of the SiO₂ dielectric layer 107.

It also should be noted that: in this embodiment, the N-type ion-implanted region 111 is formed by twice ion implantations, that is to say, the N-type ion-implanted region 111 is formed by implanting N-type ions into the GaN channel layer 103 and the first barrier layer 104 after the SiN dielectric layer 106 is formed and after the SiO₂ dielectric layer 107 is formed, respectively. Specifically, after the SiN dielectric layer 106 is formed and before the SiO₂ dielectric layer 107 is formed, the N-type ions are implanted into the first barrier layer 104 and the GaN channel layer 103 for one time; and after the SiN dielectric layer 106 is formed and after the SiO₂ dielectric layer 107 is formed, the N-type ions are implanted into the first barrier layer 104 and the GaN channel layer 103 for a second time. The edge 111a of the upper portion of the N-type ion-implanted region 111 close to the gate electrode 108 is aligned with the outside edge 106a of the SiN dielectric layer 106; the edge 111b of the lower portion of the N-type ion-implanted region 111 close to the gate electrode 108 is aligned with the outside edge 107a of the SiO₂ dielectric layer 107.

Moreover, in this embodiment, the cross section of the gate electrode 108 is substantially T-shaped.

In the GaN-based HEMT device provided by the present disclosure, by forming an N-type ion-implanted region in the source and drain regions to form a heavily doped N-type GaN channel layer 103 and barrier layer; by forming the source and drain metal electrodes on the heavily doped N-type GaN channel layer 103 and barrier layer, two effects can be achieved in this way: firstly, the gate-source resistance and the gate-drain resistance are reduced by the ion-implanted region, and then the influence of metal diffusion on the gate electrode and the channel layer is reduced through ohmic contact of the heavily doped GaN channel layer 103 and barrier layer with the source and drain electrodes.

The embodiments described above are only for illustrating the technical concepts and features of the present disclosure, are preferable embodiments, and are intended to make those skilled in the art being able to understand the present disclosure and thereby implement it, and should not be concluded to limit the protective scope of this disclosure. Any equivalent variations or modifications according to the present disclosure should be covered by the protective scope of the present disclosure.

1. A GaN-based HEMT device, comprising
a gate electrode, a source electrode, a drain electrode, a substrate, a buffer layer, a GaN channel layer, a first barrier layer, a second barrier layer and a dielectric passivation layer, the substrate, the buffer layer, the GaN channel layer, the first barrier layer, the second barrier layer and the dielectric passivation layer being sequentially stacked from bottom to top,
wherein an N-type ion-implanted region is formed in the GaN channel layer and the first barrier layer, and the source electrode and the drain electrode are formed on an upper surface of the N-type ion-implanted region;
the gate electrode is formed on an upper surface of the first barrier layer and is located between the source electrode and the drain electrode;
the dielectric passivation layer encircles the gate electrode to isolate the gate electrode from the N-type ion-implanted region.

2. The GaN-based HEMT device according to claim 1, wherein a material of the first barrier layer is AlN or a combination of Al, N and one or two selected from In, Ga and Sc; the second barrier layer is an AlN barrier layer.

3. The GaN-based HEMT device according to claim 2, wherein the first barrier layer is an AlGaN, AlInN, AlScN, AlN, AlInGaN, AlInScN or AlGaScN barrier layer.

4. The GaN-based HEMT device according to claim 1, wherein the N-type ion-implanted region extends vertically downward from the upper surface of the first barrier layer into the GaN channel layer, and the N-type ion-implanted region extends into the GaN channel layer to a depth less than a thickness of the GaN channel layer.

5. The GaN-based HEMT device according to claim 4, wherein the N-type ion-implanted region extends into the GaN channel layer to a depth of 10-300 nm.

6. The GaN-based HEMT device according to claim 1, wherein an edge of the N-type ion-implanted region close to the gate electrode is aligned with an outside edge of the dielectric passivation layer.

7. The GaN-based HEMT device according to claim 6, wherein the N-type ion-implanted region is formed by one or multiple ion implantations.

8. The GaN-based HEMT device according to claim 7, wherein the dielectric passivation layer is a single layer structure, and the N-type ion-implanted region is formed by implanting N-type ions into the GaN channel layer and the first barrier layer after the dielectric passivation layer is formed.

9. The GaN-based HEMT device according to claim 7, wherein the dielectric passivation layer comprises a first dielectric layer and a second dielectric layer, and the N-type ion-implanted region is formed by implanting N-type ions into the GaN channel layer and the first barrier layer respectively after the first dielectric layer is formed and after the second dielectric layer is formed, and a portion of the edge of the N-type ion-implanted region close to the gate electrode is aligned with an outer edge of the first dielectric layer and another portion of the edge thereof is aligned with an outer edge of the second dielectric layer.

10. The GaN-based HEMT device according to claim 1, wherein the substrate is a single crystal substrate selected from single crystal silicon, gallium nitride, sapphire, and silicon carbide.

11. The GaN-based HEMT device according to claim 1, wherein the buffer layer is a multilayer structure composed of at least two selected from the group consisting of AlN, GaN, and AlGaN.

12. The GaN-based HEMT device according to claim 1, wherein a thickness of the first barrier layer is 1-50 nm; a thickness of the second barrier layer is 1-10 nm; a thickness of the dielectric passivation layer is 10-300 nm, and a width thereof is 10-1000 nm.
